(19) United States
(12) Patent Application Publication
(10) Pub. No.: US 2023/0176470 A1
(43) Pub. Date: Jun. 8, 2023

(54) METHOD OF GENERATING CURVE SUB-RESOLUTION ASSIST FEATURE (SRAF), METHOD OF VERIFYING MASK RULE CHECK (MRC), AND METHOD OF MANUFACTURING MASK INCLUDING METHOD OF GENERATING THE SAME

(71) Applicant: Samsung Electronics Co., Ltd., Suwon-si (KR)

(72) Inventors: Wooyong Cho, Hwaseong-si (KR); Useong Kim, Hwaseong-si (KR); Heejun Lee, Seoul (KR)

(21) Appl. No.: 17/860,139

(22) Filed: Jul. 8, 2022

(30) Foreign Application Priority Data
Dec. 8, 2021 (KR) 10-2021-0175210

(51) Int. Cl. G03F 1/36; G06F 30/398; G03F 7/20

(52) U.S. Cl. CPC G03F 1/36; G06F 30/398; G03F 7/70441

(57) ABSTRACT

Disclosed is a method of generating a curvilinear sub-resolution assist feature (SRAF) capable of easily generating a curvilinear SRAF satisfying mask rule check (MRC) conditions, an MRC verification method for easy MRC verification of the curvilinear SRAF, and a mask manufacturing method including the method of generating the same. The method of generating a curvilinear SRAF includes generating a curve axis for generating the curvilinear SRAF corresponding to a main feature, generating curve points on a line of the curve axis, and generating the curvilinear SRAF based on the curve points.

### CROSS-REFERENCE TO RELATED APPLICATION

This application is based on and claims priority under 35 U.S.C. § 119 to Korean Patent Application No. 10-2021-0175210, filed on Dec. 8, 2021, in the Korean Intellectual Property Office, the disclosure of which is incorporated by reference herein in its entirety.

### BACKGROUND

The inventive concept relates to a mask manufacturing method, and more particularly, to a method of generating a sub-resolution assist feature (SRAF), a method of verifying a mask rule check (MRC), and a method of manufacturing mask including the method of generating the SRAF.

In a semiconductor process, a photolithography process using a mask may be performed to form a pattern on a semiconductor substrate, such as a wafer. A mask may be simply defined as a pattern transfer body in which a pattern shape of an opaque material is formed on a transparent base material. To briefly explain the manufacturing process of the mask, after designing a required circuit and designing a layout for the circuit, mask design data obtained through optical proximity correction (OPC) is transmitted as mask tape-out (MTO) design data. Thereafter, mask data preparation (MDP) is perform based on the MTO design data, and the mask may be manufactured by performing a front end of line (FEOL) process, such as an exposure process, and a back end of line (BEOL) process, such as a defect inspection.

### SUMMARY

The inventive concept provides a method of generating a curve sub-resolution assist feature (SRAF) capable of easily generating a curvilinear SRAF satisfying a mask rule check (MRC) condition, an MRC verification method that facilitates MRC verification for a curvilinear SRAF, and a method of manufacturing a mask including a method of generating the SRAF.

In addition, the problems to be solved by the inventive concept are not limited to the problems mentioned above, and other problems may be clearly understood by those skilled in the art from the following description.

According to an aspect of the inventive concept, there is provided a method of a curvilinear SRAF including generating a curve axis for generating the curvilinear SRAF corresponding to a main feature; generating curve points on a line of the curve axis; and generating the curvilinear SRAF based on the curve points.

According to another aspect of the inventive concept, there is provided a method of verifying a MRC for a curvilinear SRAF including extracting the curvilinear SRAF; finding normal directions for edges of the curvilinear SRAF; generating curve points at positions where half-widths are symmetric on both sides of the curve point based on the normal directions; connecting the curve points to generate curve axes; and performing the MRC of the curvilinear SRAF based on the curve points and the curve axes.

According to another aspect of the inventive concept, there is provided a method of manufacturing a mask including subdividing the edge of a main feature into partition edges; generating a Manhattan-type position polygon at a distance at which a curvilinear SRAF is to be generated for each of the partition edges; generating a curve axis for generating the curvilinear SRAF by rounding the position polygon; generating curve points on the line of the curve axis; generating shape points at a distance of half-width in a shape direction, for each of the curve points; connecting the shape points to generate the curvilinear SRAF; performing MRC on the curvilinear SRAF; determining whether there is a defect in performing the MRC; if there is no defect, transferring the layout image including the main feature and the curvilinear SRAF as mask tape-out (MTO) design data; preparing mask data based on the MTO design data; and exposing a substrate for a mask based on the mask data.

### BRIEF DESCRIPTION OF THE DRAWINGS

Embodiments of the inventive concept will be more clearly understood from the following detailed description taken in conjunction with the accompanying drawings in which:

FIG. 1 is a flowchart schematically illustrating a process of a method of generating a curvilinear sub-resolution assist feature (SRAF), according to an example embodiment of the inventive concept;

FIGS. 2A to 2E are conceptual diagrams illustrating a process from subdividing an edge of a main feature into partition edges to generating curve points in the method of generating a curvilinear SRAF of FIG. 1;

FIG. 3 is a conceptual diagram schematically illustrating the operations of forming shape points and generating the curvilinear SRAF in the method of generating a curvilinear SRAF of FIG. 1;

FIGS. 4A to 6B are conceptual views for explaining in more detail the operations of forming shape points and generating the curvilinear SRAF in the method of generating a curvilinear SRAF of FIG. 1;

FIGS. 7A and 7B are conceptual diagrams for explaining length verification of the curvilinear SRAF in the operation of performing MRC in the method of generating a curvilinear SRAF of FIG. 1;

FIGS. 8A and 8B are conceptual diagrams for explaining area verification of the curvilinear SRAF in the operation of performing mask rule check (MRC) in the method of generating a curvilinear SRAF of FIG. 1;

FIGS. 9A and 9B are conceptual diagrams for explaining curve axis connection angle verification and curve axis correction of the curvilinear SRAF in the operation of performing MRC in the method of generating a curvilinear SRAF of FIG. 1;

FIGS. 10A to 10E are conceptual diagrams for explaining space verification of a curvilinear SRAF in the operation of performing MRC in the method of generating a curvilinear SRAF of FIG. 1;

FIG. 11 is a flowchart schematically illustrating a process of an MRC verification method for a curvilinear SRAF, according to an example embodiment of the inventive concept;

FIGS. 12A to 12C are conceptual diagrams for explaining an MRC verification method for the curvilinear SRAF of FIG. 11; and

FIG. 13 is a flowchart schematically illustrating a process of a mask manufacturing method including a method of generating a curvilinear SRAF, according to an example embodiment of the inventive concept.

### DETAILED DESCRIPTION OF THE EMBODIMENTS

Hereinafter, example embodiments of the inventive concept are described in detail with reference to the accompanying drawings. The same reference numerals are used for the same components in the drawings, and descriptions thereof, which have already been given are omitted.

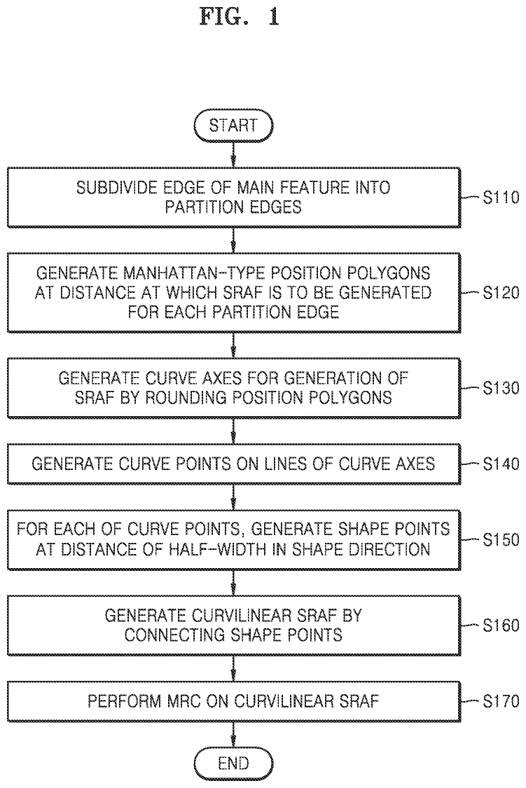

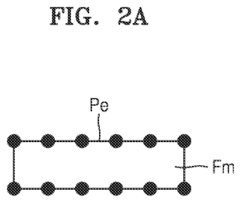

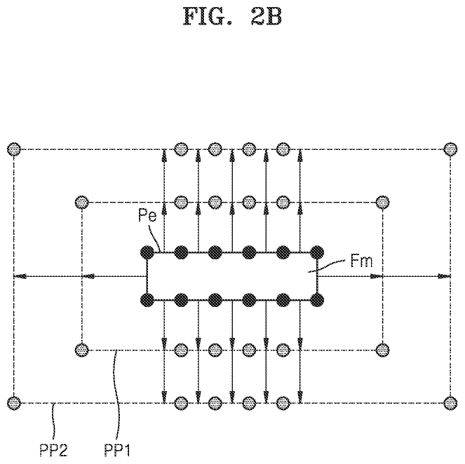

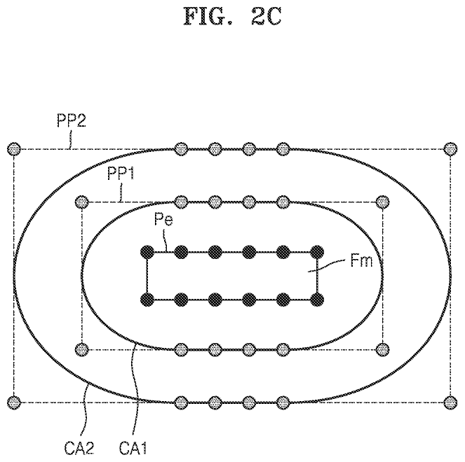

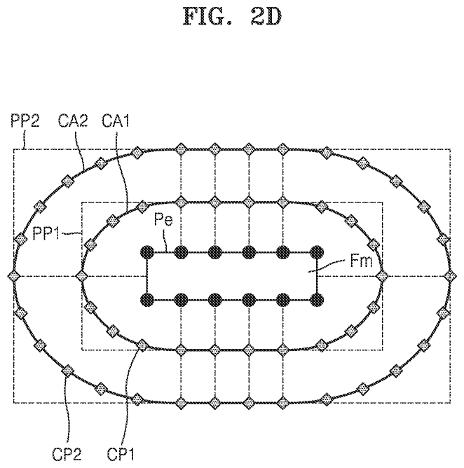

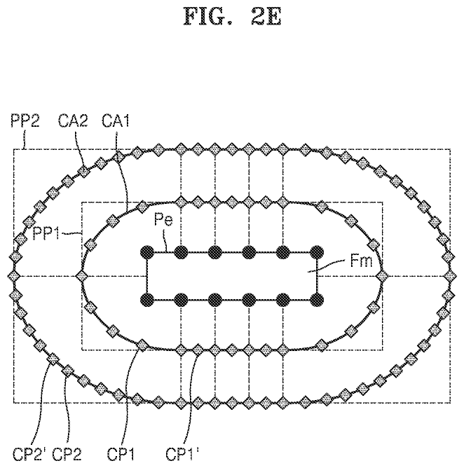

FIG. 1 is a flowchart schematically illustrating a process of a method of generating a curvilinear sub-resolution assist feature (SRAF), according to an example embodiment of the inventive concept, and FIGS. 2A to 2E are conceptual diagrams illustrating a process from subdividing an edge of a main feature into partition edges to generating curve points in the method of generating a curvilinear SRAF of FIG. 1.

Referring to FIGS. 1 and 2A, in the method of generating a curvilinear SRAF, according to the present embodiment, first, an edge of a main feature Fm is subdivided into partition edges Pe (S110). Here, the main feature Fm may correspond to a target pattern to be formed on a substrate, such as a wafer. Such a target pattern may be formed by transferring a pattern on a mask onto a substrate through an exposure process. Accordingly, first, a layout of the pattern on the mask corresponding to the target pattern, that is, a mask layout, may be designed. For reference, in general, the shape of the target pattern may be different from the shape of the pattern on the mask due to the nature of the exposure process. In addition, because the pattern on the mask is reduced-projected and transferred onto the substrate, the pattern on the mask may have a larger size than the target pattern.

On the other hand, as the pattern is refined, an optical proximity effect (OPE) due to the influence between neighboring patterns occurs during the exposure process, and to overcome this, optical proximity correction (OPC), which suppresses OPE occurrence by correcting the mask layout, may be performed. The OPC is largely divided into two types, one is rule-based OPC, and the other is simulation-based or model-based OPC. The model-based OPC may be advantageous in terms of time and cost because the model-based OPC uses only measurement results of representative patterns without the need to measure all of a large number of test patterns. On the other hand, the OPC may include not only modifying the mask layout, but also adding sub-lithographic features called serifs on the corners of the pattern, or adding an SRAF, such as scattering bars in a broad sense. Accordingly, generating a curvilinear SRAF of the present embodiment may be included in the OPC. On the other hand, when patterns in a chip are formed in a high-density area and a low-density area, an SRAF is an auxiliary pattern introduced to solve the problem that deviation caused by the OPC occurs due to different diffraction patterns in each region due to optical characteristics, and this SRAF is not a pattern actually formed on the wafer.

A brief description of the OPC process is as follows. First, basic data for OPC is prepared. Next, an OPC model including an optical OPC model and an OPC model for photoresist (PR) is generated. Thereafter, layout images or data on which OPC has been performed through a simulation process using the OPC model are obtained. Then, mask rule check (MRC) is performed on the layout images on which OPC has been performed (referred to as OPC layout images). Here, the MRC may refer to a check for restrictions on a width or an interval at which a pattern should be maintained when manufacturing a mask. For example, when manufacturing a mask, there may be a limitation in which a width of the pattern cannot be made less than a set minimum width or an interval between patterns cannot be made less than a set minimum interval. These limitations may be referred to as mask process limitations. Accordingly, performing or verifying the MRC may refer to a process of checking whether the limitations stated above are observed with respect to the mask layout. Through the MRC, a final OPC layout image may be obtained. Final OPC layout images may be provided to the mask manufacturing team as mask tape-out (MTO) design data for mask manufacturing later.

On the other hand, as the pattern has recently been refined, as a result of performing OPC to overcome the MRC constraint of the existing Manhattan mask shape and to improve a mask distribution and mask error enhancement factor (MEEF), a curvilinear mask shape has been introduced. An SRAF also needs a curvilinear SRAF to serve as an assist feature optimized for a curvilinear main feature, and therefore, a curvilinear SRAF that satisfies the MRC needs to be generated. However, there is a limitation in MRC verification for a curvilinear SRAF and clean-up of MRC errors using conventional SRAF generation technology and a conventional MRC verification method.

A rule for subdividing the edge of the main feature Fm into partition edges Pe may be defined in various ways. For example, in FIG. 2A, the partition edges Pe may be generated by dividing the edge of the main feature Fm at predetermined intervals. Black dots may correspond to subdivision points for edge division.

Referring to FIGS. 1 and 2B, after subdividing into partition edges Pe, Manhattan-type position polygons PP1 and PP2 are generated at the distance at which the SRAF is to be generated for each partition edge Pe (S120). Although two types of position polygons PP1 and PP2 are exemplified in FIG. 2B, one type or three or more types of position polygons may be generated corresponding to one main feature Fm.

Referring to FIGS. 1 and 2C, after the position polygons PP1 and PP2 are generated, the position polygons PP1 and PP2 are rounded to generate curve axes CA1 and CA2 (S130). In FIG. 2C, the curve axes CA1 and CA2 may be generated by rounding both position polygons PP1 and PP2 in the x-axis direction (e.g., in the direction of the longitudinal axis of the main feature Fm). As a detailed example, the curve axes CA1 and CA2 may be generated by defining the lines of the curve axes CA1 and CA2, based on the segment of the position polygons PP1 and PP2. For example, by making specific points of the segment satisfy an elliptic equation, the curve axes CA1 and CA2 may be generated so that the line of the curve axes CA1 and CA2 constitutes the corresponding ellipse.

Referring to FIGS. 1, 2D, and 2E, after the curve axes CA1 and CA2 are generated, curve points CP1 and CP2 are generated on the lines of the curve axes CA1 and CA2 (S140). The curve points CP1 and CP2 may be variously generated on the lines of the curve axes CA1 and CA2, based on a predetermined rule. For reference, points on the position polygons PP1 and PP2 in FIG. 2B and points on the curve axes CA1 and CA2 in FIG. 2C may be points corresponding to subdivision points for dividing an edge in the main feature Fm. Accordingly, those points are not directly related to the curve points CP1 and CP2, but as may be seen by comparing FIG. 2C with FIG. 2D, in general, points on the curve axes CA1 and CA2 may be included as part of the curve points CP1 and CP2. The curve points CP1 and CP2 may be more than points on the curve axes CA1 and CA2 of FIG. 2C. On the other hand, as shown in FIG. 2E, additional curve points CP1′ and CP2′ may be further generated between the curve points CP1 and between the curve points CP2 as needed.

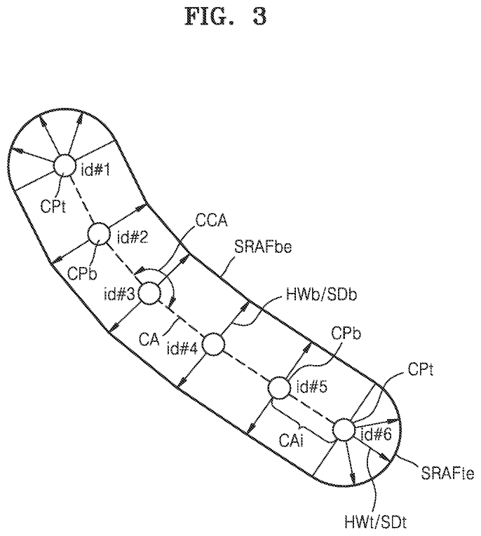

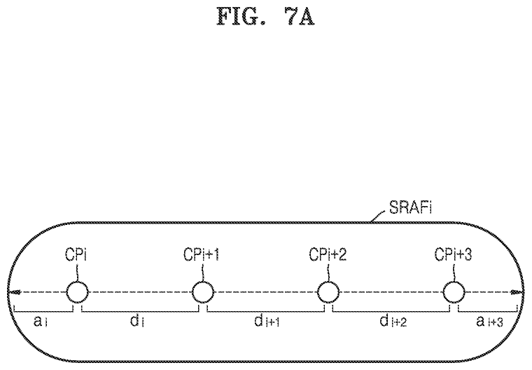

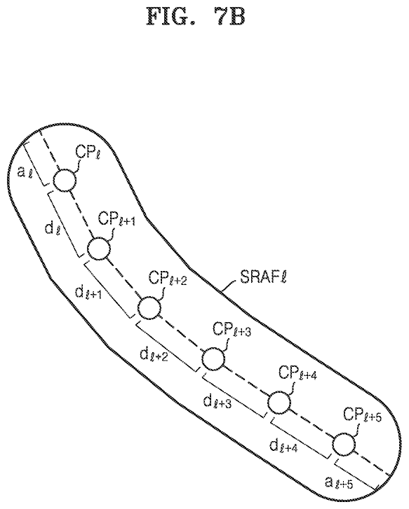

Thereafter, for each of the curve points, shape points are generated at a distance of half-width in the shape direction (S150), and a curvilinear SRAF is generated by connecting the shape points (S160). The generating the shape points (S150) and the generating the curvilinear SRAF (S160) are described in more detail with the descriptions of FIGS. 3 to 6B. Following operation S160, MRC is performed on the generated curvilinear SRAF (S170). The operation of performing MRC (S170) will be described in more detail with descriptions of FIGS. 7A to 10E.

The method of generating a curvilinear SRAF, according to the present embodiment, may generate the curvilinear SRAF by subdividing the edge of the main feature into partition edges, generating a position polygon, generating curve axes and curve points through rounding processing, and then generating shape points, based on curve axes and curve points. As such, in the method of generating a curvilinear SRAF of the present embodiment, by generating the curvilinear SRAF, based on points, such as curve points and shape points, the curvilinear SRAF satisfying the MRC condition may be easily generated. In addition, MRC verification for the generated curvilinear SRAF may be very easy.

For reference, in the case of the existing curvilinear SRAF generation method, there is a problem in that it may not flexibly respond to the MRC condition by generating the curvilinear SRAF only with angle and distance information from the corner of the main feature without considering the width and space of the main feature. Therefore, the existing curvilinear SRAF generation method has been utilized only for initial guide SRAF generation during optimization by using inverse lithography technology (ILT). For reference, ILT technology is one of OPCs. In general, OPC is performed by dividing the edge of the pattern into small pieces and moving the small pieces up, down, left, and right or inserting auxiliary features in the form of rectangles, based on rules, to correct distortion caused by diffraction. On the other hand, calculating the image transferred from the photomask to the wafer surface may be obtained by mathematically expressing the optical system. This is called a forward function, and ILT is technology to obtain the inverse function of this forward function. Because ILT requires a lot of computations, ILT has been utilized in such a way that ILT is locally used where a pattern is complex, rather than applied to an entire chip.

FIG. 3 is a conceptual diagram schematically illustrating the operations of forming shape points and generating the curvilinear SRAF in the method of generating a curvilinear SRAF of FIG. 1. The descriptions already given with respect to FIGS. 1 to 2E are briefly given or omitted.

Referring to FIG. 3, FIG. 3 shows a curvilinear SRAF generated based on the curve points CP, and the curve points CP may include two tip points CPt at both ends and at least one bridge point CPb between the two tip points CPt. For example, a first tip point CPt may be at a first end of the series of curve points CP, and a second tip point CPt may be at a second end of the series of curve points CP. The curve points CP may have ID numbers defined in one direction. For example, from upper left to lower right, six curve points CP may be defined as id#1 to id#6. On the other hand, the dashed lines between the curve points CP may correspond to the curve axes CA, and as described above, the curve axes CA may be generated first and the curve points CP may be generated on the curve axes CA.

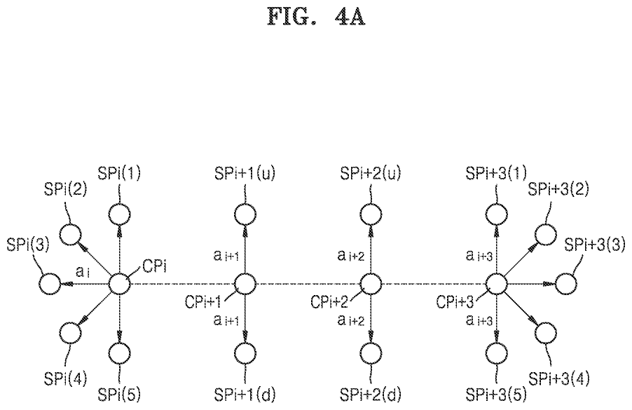

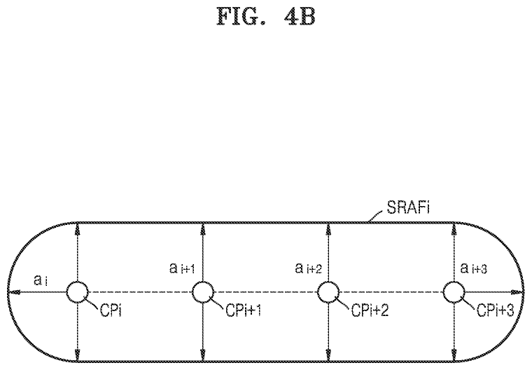

For the generation of the curvilinear SRAF, for each of the curve points CP, shape points are generated at a half-width HW distance in the shape direction SD (see shape points SPi(1), etc. in FIG. 4A). Here, the shape direction SD may be defined differently depending on the types of the curve points CP. For example, the shape direction SDb of the bridge point CPb may be defined as a normal direction of the curve axis CA of the corresponding bridge point CPb. Meanwhile, the shape direction SDt of the tip point CPt may be defined as a radial direction of the corresponding tip point CPt. On the other hand, the half-width HW may also vary depending on the types of the curve points CP. For example, the half-width HWb of the bridge point CPb may be bilaterally symmetric with respect to the curve axis CA of the corresponding bridge point CPb. In addition, the half-width HWb of the bridge point CPb may be ½ or less of the reference width of the SRAF required for the MRC. On the other hand, the half-width HWt of the tip point CPt may correspond to a radius from the corresponding tip point CPt, and may be less than or equal to ½ of the reference width of the SRAF required for the MRC.

The shape points may be generated when the shape direction and half-width are set for the curve points CP. For example, shape points may be created at a distance of half-width in the shape direction, as in FIG. 4A and the like. When the shape points are generated, the curvilinear SRAF may be generated by connecting adjacent shape points to generate an edge of the curvilinear SRFA. The edge of the curvilinear SRFA may include an SRFA bridge edge SRAFbe corresponding to the bridge point CPb and an SRFA tip edge SRAFte corresponding to the tip point CPt.

On the other hand, a curve point interval CAi may be defined as a distance between adjacent curve points CP. In addition, for one curve point CP, a curve axis connection angle CCA between lines of the curve axis CA connected to the curve points CP on both sides of the curve point CP may be defined. The half-width HWt and the curve point interval CAi may be used for length verification or area verification of the curvilinear SRAF in MRC, which is described later. In addition, the curve axis connection angle CCA may be used to verify the curve axis connection angle of the curvilinear SRAF in the MRC.

On the other hand, the curvilinear SRAF may be classified as a line-type and an iso-type. The line-type curvilinear SRAF may include a plurality of curve points CP and may have an elongated shape in one direction. The curvilinear SRAF of FIG. 3 is line-type, and accordingly, the curve points CP may be classified as line-type.

On the other hand, the iso-type curvilinear SRAF may include one curve point CP as a center point and may have a circular shape. In the case of the iso-type, the center point may function similarly to the tip point in the line-type. In other words, a shape direction may be defined in the radial direction of the center point, and the half-width may correspond to the radius at the center point, and may be less than or equal to ½ of the reference width of SRAF required for the MRC. However, in the case of a line-type tip point, the edge of the curvilinear SRAF is formed in a semicircle shape, but in the case of an iso-type center point, the edge of the curvilinear SRAF may be formed in a circular shape.

FIGS. 4A to 6B are conceptual views for explaining in more detail the operations of forming shape points and generating the curvilinear SRAF in the method of generating a curvilinear SRAF of FIG. 1. The descriptions already given with respect to FIGS. 1 to 3 are briefly given or omitted.

Referring to FIGS. 4A and 4B, four curve points CPi, CPi+1, CPi+2, and CPi+3 may be generated through the process of FIGS. 2A to 2E described above. After the curve points CPi, CPi+1, CPi+2, and CPi+3 are formed, for each of the curve points CPi, CPi+1, CPi+2, and CPi+3, shape points SPi, SPi+1, SPi+2, and SPi+3 are generated at the distances of the half-widths aᵢ, aᵢ₊₁, aᵢ₊₂, and aᵢ₊₃ in the shape direction. On the other hand, corresponding to each of the bridge points CPi+1 and CPi+2 based on the symmetry concept, two shape points may be generated. For example, two shape points SPi+1(u) and SPi+1(d) may be generated for the first bridge point CPi+1, and two shape points SPi+2(u) and SPi+2(d) may be generated for the second bridge point CPi+2. On the other hand, in a case of the tip points CPi and CPi+3, a plurality of shape points corresponding to a semicircle may be generated. For example, five shape points SPi(1) to SPi(5) may be generated for the first tip point CPi, and five shape points SPi+3(1) to SPi+3(5) may be generated for the second tip point CPi+3. In FIG. 4A, five shape points are generated at each of the tip points CPi and CPi+3, but the number of shape points is not limited to 5. After the shape points SPi, SPi+1, SPi+2, and SPi+3 are generated, the adjacent shape points SPi, SPi+1, SPi+2, and SPi+3 are connected to each other, so that the curvilinear SRAF SRAFi shown in FIG. 4B is generated. The curvilinear SRAF SRAFi of FIG. 4B may be, for example, line-type.

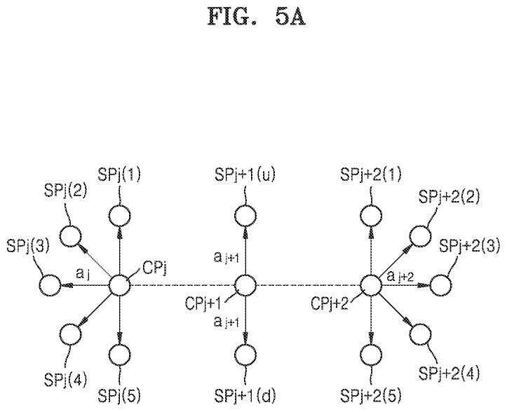

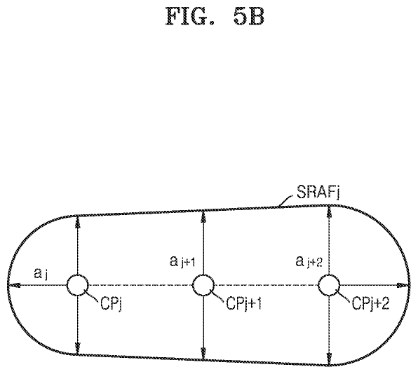

Referring to FIGS. 5A and 5B, three curve points CPj, CPj+1, and CPj+2 may be generated through the process of FIGS. 2A to 2E described above. After the curve points CPj, CPj+1, and CPj+2 are formed, for each of the curve points CPj, CPj+1, and CPj+2, shape points SPj, SPj+1, and SPj+2 are generated at the distances of the half-widths aⱼ, aⱼ₊₁, and aⱼ₊₂ in the shape direction, and the adjacent shape points SPj, SPj+1, and SPj+2 are connected to each other, so that the curvilinear SRAF SRAFj shown in FIG. 5B is generated. For example, two shape points SPj+1(u) and SPj+1(d) may be generated for the first bridge point CPj+1. In addition, in a case of the tip points CPj and CPj+2, a plurality of shape points corresponding to a semicircle may be generated. For example, five shape points SPj(1) to SPj(5) may be generated for the first tip point CPj, and five shape points SPj+2(1) to SPj+2(5) may be generated for the second tip point CPj+2. The curvilinear SRAF SRAFj of FIG. 5B may be, for example, line-type.

On the other hand, comparing the curvilinear SRAF SRAFi of FIG. 4B with the curvilinear SRAF SRAFj of FIG. 5B, in a case of the curvilinear SRAF SRAFi of FIG. 4B, half-widths aᵢ, aᵢ₊₁, aᵢ₊₂, and aᵢ₊₃ corresponding to the curve points CPi, CPi+1, CPi+2, and CPi+3 are set to the same size, and accordingly, the width of the curvilinear SRAF SRAFi of FIG. 4B may be constant. In contrast, in a case of the curvilinear SRAF SRAFj of FIG. 5B, the half-widths aⱼ, aⱼ₊₁, and aⱼ₊₂ corresponding to the curve points CPj, CPj+1, and CPj+2 may be set to different sizes. Accordingly, the width of the curvilinear SRAF SRAFj of FIG. 5B may not be constant.

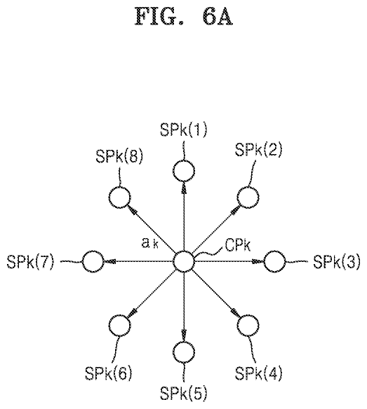

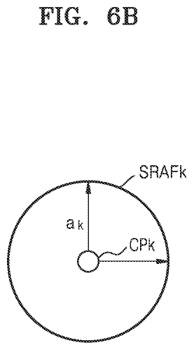

Referring to FIGS. 6A and 6B, one curve point CPk may be generated through the process of FIGS. 2A to 2E described above. The curve point CPk may be, for example, a center point. After forming the curve point CPk, shape points SPk(1) to SPk(8) may be generated at a distance of half-width aₖ in the shape direction with respect to the curve point CPk. In FIG. 6A, eight shape points SPk(1) to SPk(8) are generated, but the number of shape points is not limited to eight. Then, the curvilinear SRAF SRAFk shown in FIG. 6B is generated by connecting the adjacent shape points SPk(1) to SPk(8) to each other. The curvilinear SRAF SRAFk of FIG. 6B may be, for example, iso-type.

FIGS. 7A and 7B are conceptual diagrams for explaining length verification of the curvilinear SRAF in the operation of performing MRC in the method of generating a curvilinear SRAF of FIG. 1. The descriptions already given with respect to FIGS. 1 to 6B are briefly given or omitted.

Referring to FIGS. 7A and 7B, the curvilinear SRAF SRAFi of FIG. 7A is generated based on four curve points CPi, CPi+1, CPi+2, and CPi+3, and the length thereof may be calculated as in Equation (1).

SRAFi(length)=aᵢ+dᵢ+dᵢ₊₁+dᵢ₊₂+aᵢ₊₃ Equation (1):

where aᵢ and aᵢ₊₃ are half-widths corresponding to the tip points CPi and CPi+3, and dᵢ, dᵢ₊₁, and dᵢ₊₂ may mean a curve point interval between two adjacent tip points.

The curvilinear SRAF SRAFl of FIG. 7B is generated based on six curve points CPl, CPl+1, CPl+2, CPl+3, CPl+4, and CPl+5, and the length thereof may be calculated as in Equation (2).

SRAFl(length)=aₗ+dₗ+dₗ₊₁+dₗ₊₂+dₗ₊₃+dₗ₊₄+aₗ₊₅ Equation (2):

where aₗ and aₗ₊₅ are half-widths corresponding to tip points CPl and CPl+5, and dₗ, dₗ₊₁, dₗ₊₂, dₗ₊₃, and dₗ₊₄ may mean a curve point interval between two adjacent tip points. On the other hand, although the curvilinear SRAF SRAFl of FIG. 7B has a curved shape compared to the curvilinear SRAF SRAFi of FIG. 7A, a method of obtaining the length of the curvilinear SRAF may be substantially the same.

After all, the length of the curvilinear SRAF may be generalized to the sum of a half-width corresponding to each of the two tip points and the curve point intervals between every pair of adjacent curve points. In the MRC verification, the length of the curvilinear SRAF may be verified by comparing whether the length of the curvilinear SRAF obtained by the method described above is equal to or less than the reference length of the SRAF required for the MRC. In addition, for the line-type only, the length of the curvilinear SRAF may be verified by the above method, and for the iso-type, the length of the curvilinear SRAF may not be verified.

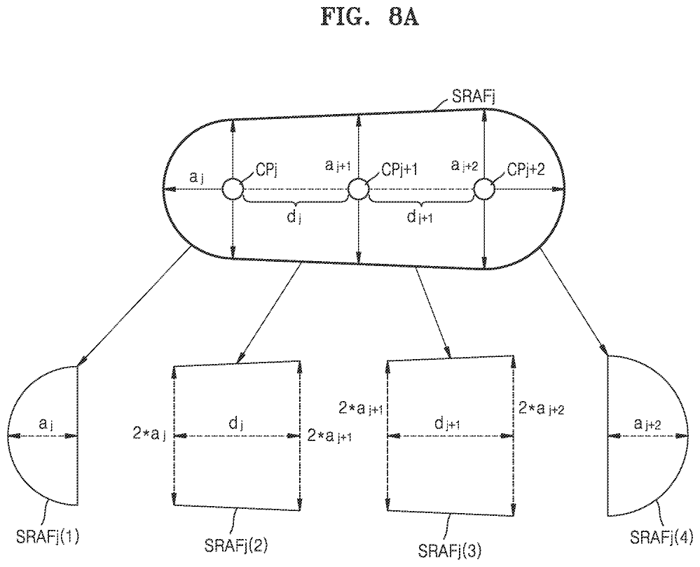

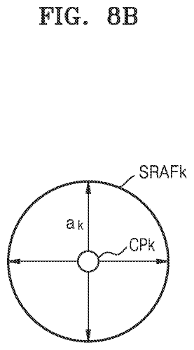

FIGS. 8A and 8B are conceptual diagrams for explaining area verification of the curvilinear SRAF in the operation of performing MRC in the method of generating a curvilinear SRAF of FIG. 1. The descriptions already given with respect to FIGS. 1 to 7B are briefly given or omitted.

Referring to FIGS. 8A and 8B, the curvilinear SRAF SRAFj of FIG. 8A is generated based on three curve points CPj, CPj+1, and CPj+2, and the area thereof may be calculated as in Equation (3).

SRAFj(area)=(π*aⱼ²)/2+dⱼ*(aⱼ+aⱼ₊₁)+dⱼ₊₁*(aⱼ₊₁+aⱼ₊₂)+(π*aⱼ₊₂²)/2 Equation (3):

Here, aⱼ and aⱼ₊₂ are half-widths corresponding to the tip points CPj and CPj+2, and dⱼ and do may mean a curve point interval between two adjacent tip points. On the other hand, in Equation (3), the first term may be an area corresponding to the curvilinear SRAF portion SRAFj(1) corresponding to the left semicircle, the second term may be an area corresponding to the curvilinear SRAF portion SRAFj(2) corresponding to the second trapezoid, the third term may be an area corresponding to the curvilinear SRAF portion SRAFj(3) corresponding to the third trapezoid, and the fourth term may be an area corresponding to the curvilinear SRAF SRAFj(4) corresponding the right semicircle.

The curvilinear SRAF SRAFk of FIG. 8B is generated based on one curve point CPk, and the area thereof may be calculated as π*aₖ². On the other hand, the curvilinear SRAF SRAFj of FIG. 8A may correspond to the line-type, and the curvilinear SRAF SRAFk of FIG. 8B may correspond to the iso-type.

After all, the area of the line-type curvilinear SRAF may be generalized to the sum of the area of a semicircle of which a radius is a half-width corresponding to each of the two tip points and the area of two trapezoids having a curve point interval between two adjacent curve points as a height and twice the half-width of each of the two curve points as an upper side and a lower side. In addition, the area of an iso-type curvilinear SRAF may be generalized to the area of a circle of which a radius is the half-width of the curve point. In the MRC verification, the area of the curvilinear SRAF may be verified by comparing whether the area of the curvilinear SRAF obtained by the above method is equal to or less than the reference area of the SRAF required for the MRC.

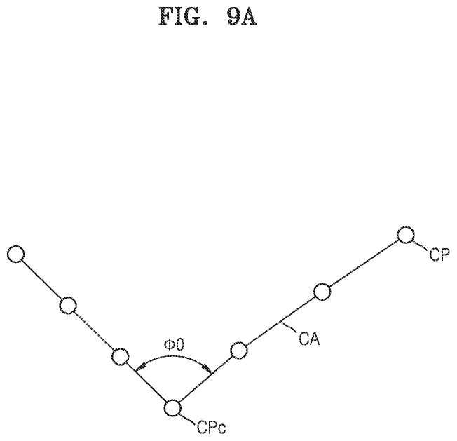

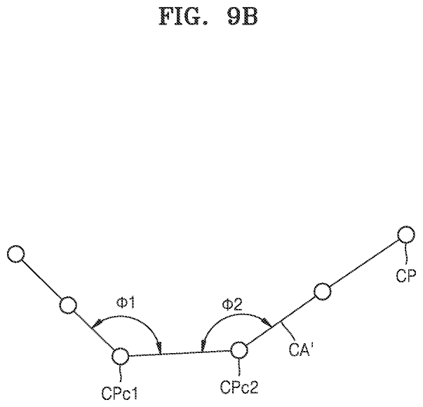

FIGS. 9A and 9B are conceptual diagrams for explaining a curve axis connection angle verification and a curve axis correction of the curvilinear SRAF in the operation of performing MRC in the method of generating a curvilinear SRAF of FIG. 1. The descriptions already given with respect to FIGS. 1 to 8B are briefly given or omitted.

Referring to FIG. 9A, a curve axis connection angle of the curvilinear SRAF may be verified by comparing whether the curve axis connection angle of the curvilinear SRAF is equal to or greater than the reference curve axis connection angle of the SRAF required for the MRC. For example, in a case of the central curve point CPc among the seven curve points CP of FIG. 9A, a curve axis connection angle φ0 between the lines of the curve axis CA connected to curve point CP on either sides thereof is relatively much smaller than the curve axis connection angles corresponding to the other curve points CP. Accordingly, MRC may be performed for the curve axis connection angle φ0 of the central curve point CPc. In MRC, if the curve axis connection angle φ0 of the central curve point CPc is less than the reference curve axis connection angle θ0 of the SRAF required for the MRC, it is determined that the MRC is violated, and in such a case, the curve axis CA may need to be corrected.

Referring to FIG. 9B, a line of new curve axes CA′ may be generated by removing the central curve point CPc among the seven curve points CP of FIG. 9A and connecting the remaining curve points CP. The curve axis connection angle of the curve points CP on the line of the new curve axes CA′ may be greater than the reference curve axis connection angle of the SRAF required by the MRC. For example, in FIG. 9B, each of the curve axis connection angles φ1 and φ2 of the two central curve points CPc1 and CPc2 may be equal to or greater than the reference curve axis connection angle θ0. Based on the line of the remaining curve points CP and the new curve axis CA′, by generating the curvilinear SRAF through the process described in the description of FIG. 3, curvilinear SRAF may be generated with automatically verified curve axis connection angle.

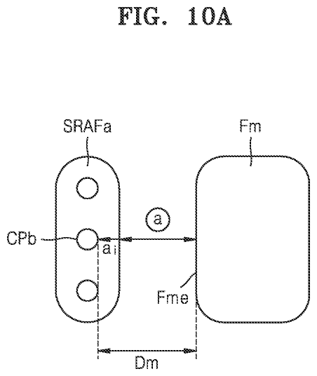

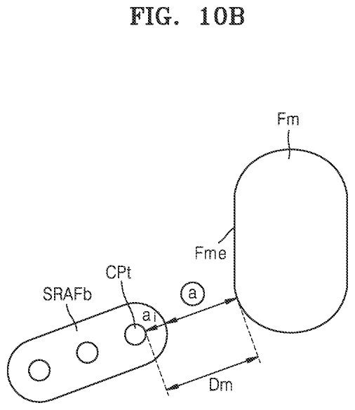

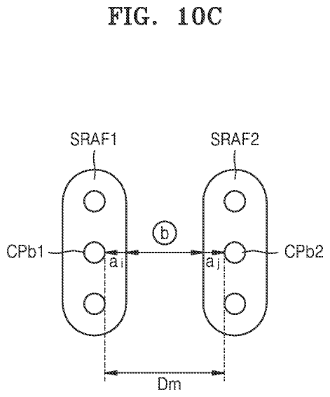

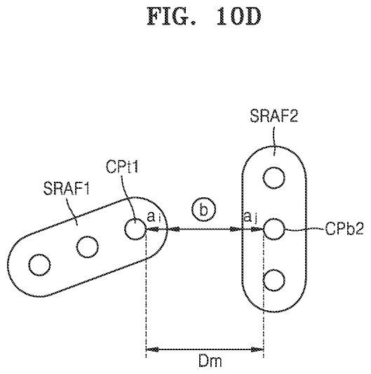

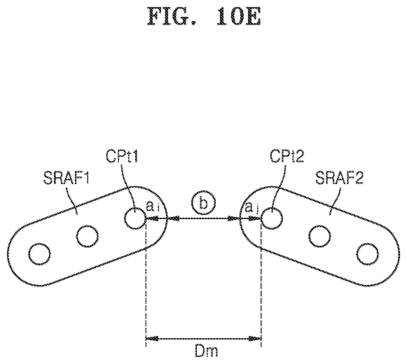

FIGS. 10A to 10E are conceptual diagrams for explaining space verification of a curvilinear SRAF in the operation of performing MRC in the method of generating a curvilinear SRAF of FIG. 1. The descriptions already given with respect to FIGS. 1 to 9B are briefly given or omitted.

Referring to FIGS. 10A and 10B, a space \textcircled{a} between a curvilinear SRAF SRAFa or SRAFb and a main feature Fm may be calculated as a distance obtained by subtracting the half-width aᵢ of the corresponding curve point from the shortest distance Dm between any one of the curve points of the curvilinear SRAF SRAFa and an edge Fme of the main feature Fm. For example, it may be calculated by \textcircled{a}=Dm−aᵢ. In MRC verification, the space of the curvilinear SRAF may be verified by determining whether the space of the curvilinear SRAF obtained by the above-described method is equal to or greater than the reference space of the SRAF required for the MRC. On the other hand, FIG. 10A shows the space \textcircled{a} between the bridge point CPb of the curvilinear SRAF SRAFa and the main feature Fm, and FIG. 10B shows the space \textcircled{a} between a tip point CPt of the curvilinear SRAF SRAFb and the main feature Fm.

Referring to FIGS. 10C to 10E, the space \textcircled{b} between two curvilinear SRAFs SRAF1 and SRAF2 may be calculated as a distance obtained by subtracting the half-widths aᵢ and aⱼ of each of the curve points from the shortest distance Dm between any one curve point of the curvilinear SRAF SRAF1 and any one curve point of the curvilinear SRAF SRAF2. For example, it may be calculated by \textcircled{b}=Dm−aᵢ−aⱼ. In the MRC verification, the space of the curvilinear SRAF may be verified by determining whether the space of the curvilinear SRAF obtained by the above method is equal to or greater than the reference space of the SRAF required for the MRC. On the other hand, FIG. 10C shows a space \textcircled{b} between the bridge point CPb1 of the curvilinear SRAF SRAF1 and a bridge point CPb2 of the curvilinear SRAF SRAF2, FIG. 10D shows a space \textcircled{b} between a tip point CPt1 of the curvilinear SRAF SRAF1 and the bridge point CPb2 of the curvilinear SRAF SRAF2, and FIG. 10E shows a space \textcircled{b} between a tip point CPt1 of the curvilinear SRAF SRAF1 and a tip point CPt2 of the curvilinear SRAF SRAF2.

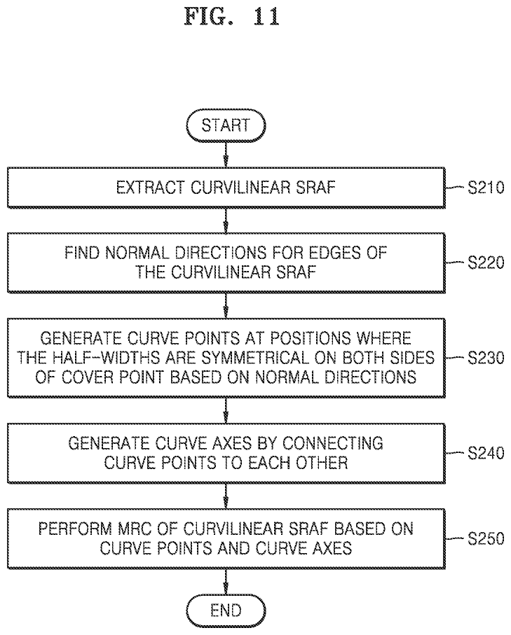

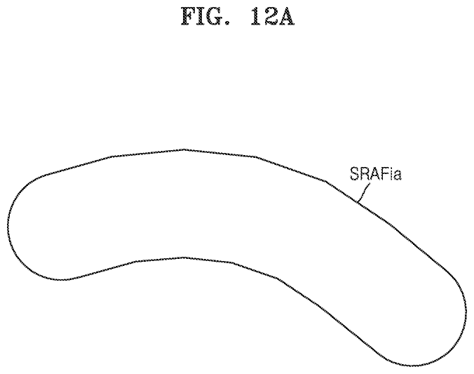

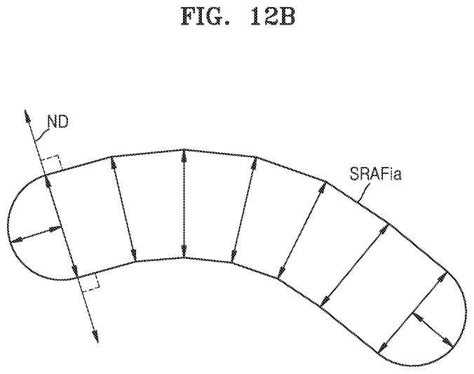

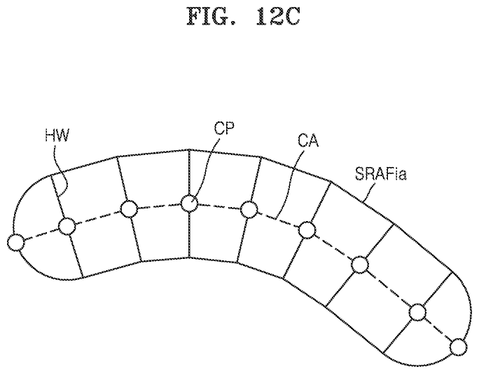

FIG. 11 is a flowchart schematically illustrating a process of an MRC verification method for a curvilinear SRAF according to an example embodiment of the inventive concept, and FIGS. 12A to 12C are conceptual diagrams for explaining an MRC verification method for the curvilinear SRAF of FIG. 11. The descriptions already given with respect to FIGS. 1 to 10E are briefly given or omitted.

Referring to FIGS. 11 and 12A, in the method of verifying MRC for the curvilinear SRAF of the present embodiment, first, the curvilinear SRAF SRAFia is extracted (S210). For example, when the curvilinear SRAF SRAFia, as shown in FIG. 12A, has already been generated, shape information on the corresponding curvilinear SRAF SRAFia may be extracted. On the other hand, the curvilinear SRAF SRAFia may be generated by a method other than the method of generating a curvilinear SRAF of FIG. 1.

Referring to FIGS. 11 and 12B, after the extraction of the curvilinear SRAF SRAFia, normal directions ND for the edges of the curvilinear SRAF SRAFia are found (S220). For example, edges of the curvilinear SRAF SRAFia, as shown in FIG. 12A are divided, and normal directions ND are found for each of the edges. On the other hand, as indicated by the double-headed arrows in FIG. 12B, the normal direction may be selected such that there are edge pairs facing each other with respect to the normal direction.

Referring to FIGS. 11 and 12C, the curve points CP are generated at positions where the half-widths HW are symmetrical on both sides of the cover point CP based on the normal directions (S230). In order for the half-width HW to be symmetric for each of the curve points CP, the normal direction may be selected such that there is the edge pair facing each other.

After generating the curve points CP, curve axes CA are generated by connecting the curve points CP to each other (S240). Subsequently, MRC of the curvilinear SRAF is performed based on the curve points CP and the curve axes CA (S250). The curve points CP and the curve axes CA may have substantially the same characteristics as the curve axes and curve points obtained through the process of FIGS. 2A to 2E. Accordingly, as described with reference to FIGS. 7A to 10E, MRC verification for curvilinear SRAF SRAFia may include performing width verification of curvilinear SRAF, length verification of curvilinear SRAF, area verification of curvilinear SRAF, curve axis connection angle verification of curvilinear SRAF, and spatial verification of curvilinear SRAF. On the other hand, in the above-described method of generating the curvilinear SRAF, because a preset half-width is applied when generating shape points, a separate verification of the width of the curvilinear SRAF may be unnecessary. However, in a case of the curvilinear SRAF SRAFia, a width verification of the curvilinear SRAF may be performed with the generated half-width HW. For example, by determining whether the half-width HW is equal to or less than ½ of the reference width of the SRAF required for the MRC, the width verification of the curvilinear SRAF may be performed.

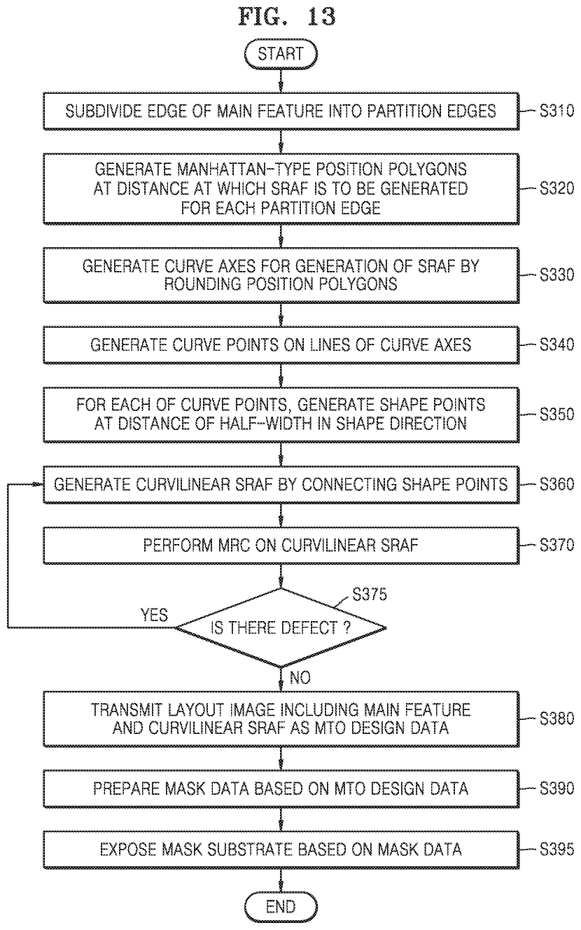

FIG. 13 is a flowchart schematically illustrating a process of a mask manufacturing method including a method of generating a curvilinear SRAF according to an example embodiment of the inventive concept. The descriptions already given with respect to FIGS. 1 to 12C are briefly given or omitted.

Referring to FIG. 13, in the mask manufacturing method (hereinafter, simply referred to as a ‘mask manufacturing method’) including the method of generating a curvilinear SRAF of the present embodiment, from the operation of subdividing into partition edges (S310) to the operation of performing the MRC (S370), it is sequentially performed. From the operation of subdividing into partition edges (S310) to performing the MRC (S370) is the same as the description of the method of generating a curvilinear SRAF of FIG. 1. For example, operations S310 to S370 of FIG. 13 correspond to operations S110 to S170 of FIG. 1, respectively.

After performing the MRC, it is determined whether there is a defect (S375). In other words, from the results of performing MRC, it is determined whether there are any violations that violate the MRC condition in the generated curvilinear SRAF. If there is a defect (S375, Yes), the flow proceeds to operation S360 of generating the curvilinear SRAF to change the shape of the curvilinear SRAF to satisfy the MRC condition. For example, the length, area, curve axis connection angle, space, etc. of the curvilinear SRAF are changed to satisfy the MRC condition. Thereafter, the flow proceeds to the operation of performing MRC again (S370).

If there is no defect (S375, No), the layout image including the main feature and curvilinear SRAF is transmitted as MTO design data to the mask production team (S380). In general, MTO may refer to requesting mask production by handing over final mask data obtained through the OPC method to a mask production team. The MTO design data may have a graphic data format used in electronic design automation (EDA) software or the like. For example, the MTO design data may have a data format such as graphic data system II (GDS2) and open artwork system interchange standard (OASIS).

Thereafter, mask data preparation (MDP) is performed based on the MTO design data (S390). The MDP may include, for example, (i) format conversion, called fracturing, (ii) augmentation including barcodes for mechanical reading, standard mask patterns for inspection, job deck, etc., and (iii) automatic and manual verification. Here, the job deck may mean generating a text file related to a series of instructions, such as arrangement information of multiple mask files, a reference dose, and an exposure speed or method.

After preparing the mask data, the mask substrate is exposed using the mask data, that is, E-beam data (S395). Here, exposure may mean, for example, E-beam writing. Here, the E-beam writing may be performed by, for example, a gray writing method using a multi-beam mask writer (MBMW). In addition, the E-beam writing may be performed using a variable shape beam (VSB) mask writer.

After the exposure process, a series of processes may be performed to complete the mask. The series of processes may include, for example, development, etching, and cleaning. In addition, the series of processes for manufacturing a mask may include a measurement process, defect inspection, or a defect repair process. In addition, a pellicle application process may be included in the series of processes. Here, the pellicle application process may refer to the process of attaching the pellicle to the mask surface to protect the mask from subsequent contamination during the delivery of the mask and the useful life of the mask, when it is confirmed that there are no contaminant particles or chemical stains through the final cleaning and inspection.

The method of manufacturing mask according to the present embodiment may include the above-described method of generating the curvilinear SRAR of FIG. 1. Accordingly, it is possible to generate optimal OPC layout images for masks including a curved pattern, and based on the optimal OPC layout images, it is possible to accurately manufacture masks including a curved pattern corresponding thereto with high reliability.

While the inventive concept has been particularly shown and described with reference to embodiments thereof, it will be understood that various changes in form and details may be made therein without departing from the spirit and scope of the following claims.

What is claimed is:

1. A method of generating a curvilinear sub-resolution assist feature (SRAF), the method comprising:
generating a curve axis for generating the curvilinear SRAF corresponding to a main feature;
generating curve points on a line of the curve axis; and
generating the curvilinear SRAF based on the curve points.

2. The method of claim 1, wherein the generating of the curve axis includes:
subdividing the edge of the main feature into partition edges;
generating a Manhattan-type position polygon at a distance to generate the curvilinear SRAF for each of the partition edges; and
rounding the Manhattan-type position polygon,
wherein the line of the curve axis is defined based on a segment of the Manhattan-type position polygon.

3. The method of claim 1,
wherein the curve points are classified as an iso-type and a line-type,
wherein the iso-type includes one center point, and
wherein the line-type includes two tip points at ends of the curvilinear SRAF, and at least one bridge point between the two tip points, and has an ID number in one direction.

4. The method of claim 3, wherein the generating of the curvilinear SRAF includes:
generating shape points at a distance of half-width in a shape direction with respect to the curve points; and
connecting the shape points to each other.

5. The method of claim 4,
wherein the shape direction is, in the case of the line-type, radial with respect to the tip point, and normal to the curve axis of the corresponding bridge point with respect to the bridge point, and
wherein the shape direction is, in the case of the isolated type, radial with respect to the center point, and
wherein the generating of the shape points includes:
generating one shape point corresponding to one of the bridge points; and
generating a plurality of shape points corresponding to the tip point or the center point.

6. The method of claim 4,
wherein a curve point interval is defined as a distance between two adjacent curve points among the curve points,
wherein for one curve point, a curve axis connection angle between lines of a curve axis is defined, the line of the curve axis being connected to a curve point on either side of the one curve point, and
wherein the half-width is equal to or less than½ of a reference width of an SRAF required by mask rule check (MRC).

7. The method of claim 6, further comprising:
after generating of the curvilinear SRAF, performing MRC on the curvilinear SRAF.

8. The method of claim 7, wherein the performing MRC includes:
for the line-type, verifying a length of the curvilinear SRAF by determining whether a length obtained by summing the half-widths corresponding to each of two tip points and curve point intervals between two adjacent curve points is equal to or less than a reference length of an SRAF required for the MRC, and
for the iso-type, not verifying the length of the curvilinear SRAF.

9. The method of claim 7, wherein the performing MRC includes:
for the line-type, verifying the area of the curvilinear SRAF by determining whether the sum of the area of a semicircle of which a radius is a half-width radius corresponding to each of the two tip points and the area of two trapezoids is equal to or less than a reference area of the SRAF required for the MRC, the trapezoid having a curve point interval between two adjacent curve points as a height and twice the half-width of each of the two curve points as an upper side and a lower side; and
for the iso-type, verifying the area of the curvilinear SRAF by determining whether the area of the circle having the half-width of the center point as the radius is equal to or less than the reference area of the SRAF required for the MRC.

10. The method of claim 7, wherein the performing MRC includes:
verifying the curve axis connection angle of the curvilinear SRAF by determining whether the curve axis connection angle is equal to or greater than a reference curve axis connection angle of the SRAF required for the MRC; and
generating lines of the curve axis by omitting the corresponding curve point and connecting the remaining curve points to each other when the curve axis connection angle with respect to any one of the curve points is less than the reference curve axis connection angle.

11. The method of claim 7,
wherein the performing MRC includes verifying a space of the curvilinear SRAF by determining whether a first space between the curvilinear SRAF and a main feature and a second space between two adjacent curvilinear SRAFs are equal to or greater than a reference space required for the MRC,
wherein, in a case between the curvilinear SRAF and the main feature, a distance obtained by subtracting the half-width of the corresponding curve point from the shortest distance between any one of the curve points and the edge of the main feature is the first space, and
wherein in a case between the two curvilinear SRAFs, a distance obtained by subtracting the half-width of each of the corresponding curve points from the shortest distance between the curve points of one of the curvilinear SRAFs and the curve points of another curvilinear SRAF is the second space.

12. A method of verifying a mask rule check (MRC) for a curvilinear sub-resolution assist feature (SRAF), the method comprising:
extracting the curvilinear SRAF;
finding normal directions for edges of the curvilinear SRAF;
generating curve points at positions where half-widths are symmetric on both sides of the curve point based on the normal directions;
connecting the curve points to generate curve axes; and
performing the MRC of the curvilinear SRAF based on the curve points and the curve axes.

13. The method of claim 12,
wherein the curve points include two tip points at ends of the curvilinear SRAF, and at least one bridge point between the two tip points, and have an ID number in one direction,
wherein a curve point interval is defined as a distance between two adjacent curve points among the curve points, and
wherein for one curve point, a curve axis connection angle is defined as an angle between lines of the curve axis connected to both curve points.

14. The method of claim 12, wherein the performing the MRC includes performing width verification of the curvilinear SRAF, length verification of the curvilinear SRAF, area verification of the curvilinear SRAF, curve axis connection angle verification of the curvilinear SRAF, and space verification of the curvilinear SRAF.

15. The method of claim 14,
wherein the performing of the width verification of the curvilinear SRAF includes determining whether the half-width is less than or equal to½ of a reference width of an SRAF required for the MRC,
wherein the performing of the length verification of the curvilinear SRAF includes for a line-type, determining whether a length obtained by summing the half-widths corresponding to each of two tip points and curve point intervals between two adjacent curve points is equal to or less than a reference length of an SRAF required for the MRC,
wherein the performing of the area verification of the curvilinear SRAF includes for the line-type, determining whether the sum of the area of a semicircle of which a radius is a half-width corresponding to each of the two tip points and the area of two trapezoids is equal to or less than a reference area of the SRAF required for the MRC, the trapezoid having a curve point interval between two adjacent curve points as a height and twice the half-width of each of the two curve points as an upper side and a lower side,
wherein the performing of the curve axis connection angle verification of the curvilinear SRAF includes determining whether a curve axis connection angle is equal to or greater than a reference curve axis connection angle of the SRAF required for the MRC, and
wherein the performing of the space verification of the curvilinear SRAF includes determining whether a first space between the curvilinear SRAF and a main feature and a second space between two adjacent curvilinear SRAFs are equal to or greater than a reference space required for the MRC.

16. A method of manufacturing a mask, the method comprising:
subdividing the edge of a main feature into partition edges;
generating a Manhattan-type position polygon at a distance at which a curvilinear sub-resolution assist feature (SRAF) is to be generated for each of the partition edges;
generating a curve axis for generating the curvilinear SRAF by rounding the position polygon;
generating curve points on the line of the curve axis;
generating shape points at a distance of half-width in a shape direction, for each of the curve points;
connecting the shape points to generate the curvilinear SRAF;
performing a mask rule check (MRC) on the curvilinear SRAF;
determining whether there is a defect in performing the MRC;
if there is no defect, transferring a layout image including the main feature and the curvilinear SRAF as mask tape-out (MTO) design data;
preparing mask data based on the MTO design data; and
exposing a substrate for a mask based on the mask data.

17. The method of claim 16,
wherein the curve points are classified as an iso-type and a line-type,
wherein the iso-type includes one center point,
wherein the line-type includes two tip points at ends of the curvilinear SRAF, and at least one bridge point between the two tip points, and has an ID number in one direction,
wherein a curve point interval is defined as a distance between two adjacent curve points among the curve points, and
wherein for one curve point, a curve axis connection angle is defined as an angle between lines of the curve axis connected to both curve points.

18. The method of claim 17,
wherein the shape direction is, in the case of the line-type, radial with respect to the tip point, normal to the curve axis of the corresponding bridge point with respect to the bridge point,
wherein the shape direction is, in the case of the isolated type, radial with respect to the center point, and
wherein the half-width is less than½ of a reference width of an SRAF required for the MRC.

19. The method of claim 18, wherein the performing the MRC includes performing width verification of the curvilinear SRAF, length verification of the curvilinear SRAF, area verification of the curvilinear SRAF, curve axis connection angle verification of the curvilinear SRAF, and space verification of the curvilinear SRAF.

20. The method of claim 19,
wherein the performing the MRC includes for the line-type, determining whether a length obtained by summing the half-widths corresponding to each of two tip points and curve point intervals between two adjacent curve points is equal to or less than a reference length of an SRAF required for the MRC,
wherein the performing of the area verification of the curvilinear SRAF includes for the line-type, determining whether the sum of the area of a semicircle of which a radius is a half-width corresponding to each of the two tip points and the area of two trapezoids is equal to or less than a reference area of the SRAF required for the MRC, the trapezoid having a curve point interval between two adjacent curve points as a height and twice the half-width of each of the two curve points as an upper side and a lower side,
wherein the performing of the curve axis connection angle verification of the curvilinear SRAF includes determining whether the curve axis connection angle is equal to or greater than a reference curve axis connection angle of the SRAF required for the MRC, and
wherein the performing of the space verification of the curvilinear SRAF includes determining whether a first space between the curvilinear SRAF and a main feature and a second space between two adjacent curvilinear SRAFs are equal to or greater than a reference space required for the MRC.
